(19) United States
(12) Patent Application Publication
(10) Pub. No.: US 2014/0252640 A1
(43) Pub. Date: Sep. 11, 2014

(54) SEMICONDUCTOR PACKAGE HAVING A MULTI-CHANNEL AND A RELATED ELECTRONIC SYSTEM

(71) Applicant: Samsung Electronics Co., Ltd., Suwon-si (KR)

(72) Inventor: Min-Keun Kwak, Cheonan-si (KR)

(73) Assignee: Samsung Electronics Co., Ltd., Suwon-si (KR)

(21) Appl. No.: 14/061,198

(22) Filed: Oct. 23, 2013

(30) Foreign Application Priority Data
Mar. 5, 2013 (KR) 10-2013-0023461

(51) Int. Cl. H01L 23/49

(52) U.S. Cl. CPC H01L 23/49
USPC 257/773

(57) ABSTRACT

A substrate including internal interconnections, first and second finger electrodes, and having first to fourth quadrants. External terminals are formed on the substrate and connected to the first and second finger electrodes via the internal interconnections. A first tower including first semiconductor chips is formed on the substrate. First conductive wires are formed between the first semiconductor chips and the first finger electrodes. A second tower including second semiconductor chips is formed on the substrate. Second conductive wires are formed between the second semiconductor chips and the second finger electrodes. The external terminals include a first group connected to the first finger electrodes and configuring a channel, and a second group connected to the second finger electrodes, and configuring another channel. The first finger electrodes are formed on the third quadrant, and the second finger electrodes are formed on the first quadrant.

### CROSS-REFERENCE TO RELATED APPLICATION

This application claims priority under 35 U.S.C. §119 to Korean Patent Application No. 10-2013-0023461 filed on Mar. 5, 2013, the disclosure of which is incorporated by reference herein in its entirety.

### BACKGROUND

1. Technical Field

The inventive concept relates to a semiconductor package having a multi-channel and a multi-tower, and a related electronic apparatus.

2. Discussion of the Related Art

As many electronic systems require light, thin, short, and small features, technologies for installing a plurality of semiconductor chips in a single package are being studied.

### SUMMARY

Exemplary embodiments of the inventive concept provide a semiconductor package in which a plurality of semiconductor chips are mounted in a single package and input/output characteristics are improved.

Exemplary embodiments of the inventive concept provide an electronic apparatus including a semiconductor package in which a plurality of semiconductor chips are mounted in a single package and input/output characteristics are improved.

In accordance with an exemplary embodiment of the inventive concept, a semiconductor package includes a substrate which has a plurality of internal interconnections, first finger electrodes, and second finger electrodes, and has first to fourth quadrants, external terminals formed on a first surface of the substrate and connected to the first and second finger electrodes via the internal interconnections, a first tower arranged on a second surface of the substrate and including a plurality of first semiconductor chips, first conductive wires formed between the first semiconductor chips and the first finger electrodes, a second tower arranged on the second surface of the substrate, spaced apart from the first tower, and including a plurality of second semiconductor chips, and second conductive wires formed between the second semiconductor chips and the second finger electrodes. The external terminals include a first group connected to the first finger electrodes and configuring a first channel, and a second group spaced apart from the first group, connected to the second finger electrodes, and configuring a second channel. The first finger electrodes are formed on the third quadrant of the substrate, and the second finger electrodes are formed on the first quadrant of the substrate.

In exemplary embodiments of the inventive concept, the first group of the external terminals may be formed on the fourth quadrant of the substrate, and the second group of the external terminals may be formed on the second quadrant of the substrate.

In exemplary embodiments of the inventive concept, the first group of the external terminals may be formed on the third quadrant of the substrate, and the second group of the external terminals may be formed on the first quadrant of the substrate.

In exemplary embodiments of the inventive concept, the first and second finger electrodes may be formed adjacent to edges of the substrate.

In exemplary embodiments of the inventive concept, each of the first and second semiconductor chips may have substantially the same horizontal width.

In exemplary embodiments of the inventive concept, upper ends of the first and second towers may be arranged at substantially the same vertical level.

In exemplary embodiments of the inventive concept, the semiconductor package may further include a third semiconductor chip mounted on the first tower and connected to the substrate. The third semiconductor chip may have a different horizontal width from the first and second semiconductor chips.

In exemplary embodiments of the inventive concept, the semiconductor package may further include a fourth semiconductor chip mounted on the second tower and connected to the third semiconductor chip. The fourth semiconductor chip may have a different horizontal width from the first, second, and third semiconductor chips.

In exemplary embodiments of the inventive concept, the semiconductor package may further include a third semiconductor chip mounted between the substrate and the first tower and connected to the substrate. The third semiconductor chip may have a different horizontal width from the first and second semiconductor chips.

In exemplary embodiments of the inventive concept, the semiconductor package may further include a fourth semiconductor chip mounted between the substrate and the second tower and connected to substrate. The fourth semiconductor chip may have a different horizontal width from the first, second, and third semiconductor chips.

In exemplary embodiment of the inventive concept, the semiconductor package may further include a first spacer mounted between the substrate and the first tower. Upper ends of the third semiconductor chip and the first spacer may be arranged at substantially the same vertical level.

In exemplary embodiment of the inventive concept, the semiconductor package may further include a second spacer mounted between the substrate and the second tower. Upper ends of the third semiconductor chip, the first spacer, and the second spacer may be arranged at substantially the same vertical level.

In accordance with an exemplary embodiment of the inventive concept, an electronic apparatus includes a controller, and a plurality of non-volatile memory packages connected to the controller. At least one of the non-volatile memory packages includes a substrate which has a plurality of internal interconnections, first finger electrodes, and second finger electrodes, and has first to fourth quadrants, external terminals formed on a first surface of the substrate and connected to the first and second finger electrodes via the internal interconnections, a first tower arranged on a second surface of the substrate and including a plurality of first semiconductor chips, first conductive wires formed between the first semiconductor chips and the first finger electrodes, a second tower arranged on the second surface of the substrate, spaced apart from the first tower, and including a plurality of second semiconductor chips, and second conductive wires formed between the second semiconductor chips and the second finger electrodes. The external terminals include a first group connected to the first finger electrodes and configuring a first channel, and a second group spaced apart from the first group, connected to the second finger electrodes, and configuring a second channel. The first finger electrodes are formed on the third quadrant of the substrate, and the second finger electrodes are formed on the first quadrant of the substrate.

In exemplary embodiments of the inventive concept, the first and second finger electrodes may be formed adjacent to edges of the substrate, and upper ends of the first and second towers may be arranged at substantially the same vertical level.

In exemplary embodiments of the inventive concept, the electronic apparatus may further include an interface connected to the controller, and a buffer memory connected to the controller.

In accordance with an exemplary embodiment of the inventive concept a semiconductor package includes a substrate including a plurality of first electrodes and a plurality of second electrodes, wherein the first electrodes are arranged at a first edge of the substrate and the second electrodes are arranged at a second edge of the substrate; a plurality of first semiconductor chips stacked on a first surface of the substrate and connected to the first electrodes via first wires; a plurality of second semiconductor chips stacked on the first surface of the substrate and connected to the second electrodes via second wires; and external terminals disposed on a second surface of the substrate and connected to the first and second semiconductor chips via internal interconnections of the substrate connected to the first and second wires, wherein at least one of the external terminals of a first channel is connected to at least one of the first electrodes via one of the internal interconnections and at least one of the external terminals of a second channel is connected to at least one of the second electrodes via another one of the internal interconnections.

The first and second electrodes are spaced apart in a diagonal direction.

The first and second electrodes include finger electrodes.

The first and second wires are conductive.

The first semiconductor chips are spaced apart from the second semiconductor chips.

### BRIEF DESCRIPTION OF THE DRAWINGS

The foregoing and other features of the inventive concept will become more apparent by describing in detail exemplary embodiments thereof with reference to the accompanying drawings in which:

FIG. 1 is a perspective view of a semiconductor package in accordance with exemplary embodiments of the inventive concept;

FIGS. 2 and 3 are layout views of a semiconductor package in accordance with exemplary embodiments of the inventive concept;

FIGS. 4 to 11 are cross-sectional views of semiconductor packages in accordance with exemplary embodiments of the inventive concept;

FIGS. 12 to 19 are perspective views and cross-sectional views of semiconductor packages in accordance with exemplary embodiments of the inventive concept; and

FIGS. 20 to 25 are perspective views and system block diagrams showing electronic apparatuses in accordance with exemplary embodiments of the inventive concept.

### DETAILED DESCRIPTION OF THE EMBODIMENTS

Exemplary embodiments of the inventive concept will now be described more fully hereinafter with reference to the accompanying drawings. The inventive concept may, however, be embodied in different forms and should not be construed as limited to the embodiments set forth herein. In the drawings, the sizes and relative sizes of layers and regions may be exaggerated for clarity. Like reference numerals may refer to the same elements throughout the specification and drawings.

It will be understood that when an element is referred to as being “connected” or “coupled” to another element, it can be directly connected or coupled to the other element or intervening elements may be present.

As used herein, the singular forms “a,” “an,” and “the” are intended to include the plural forms as well, unless the context clearly indicates otherwise.

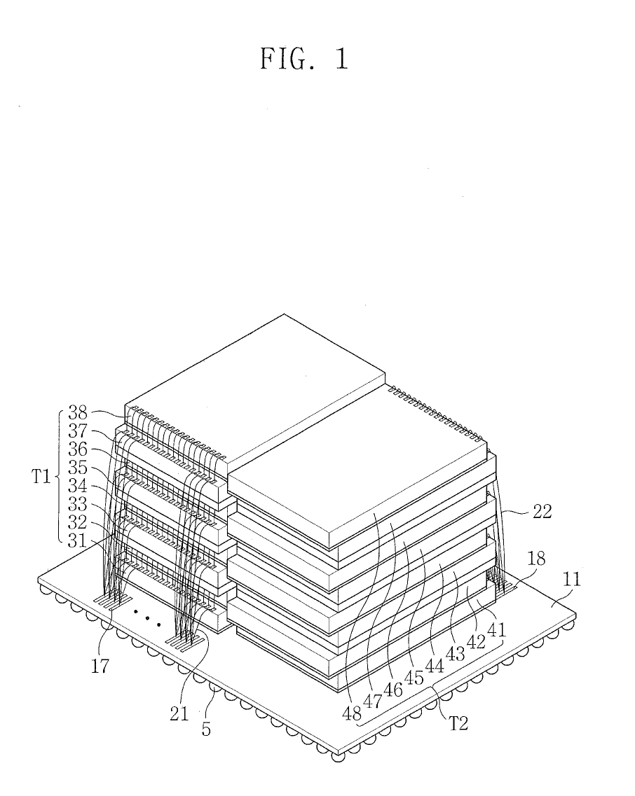

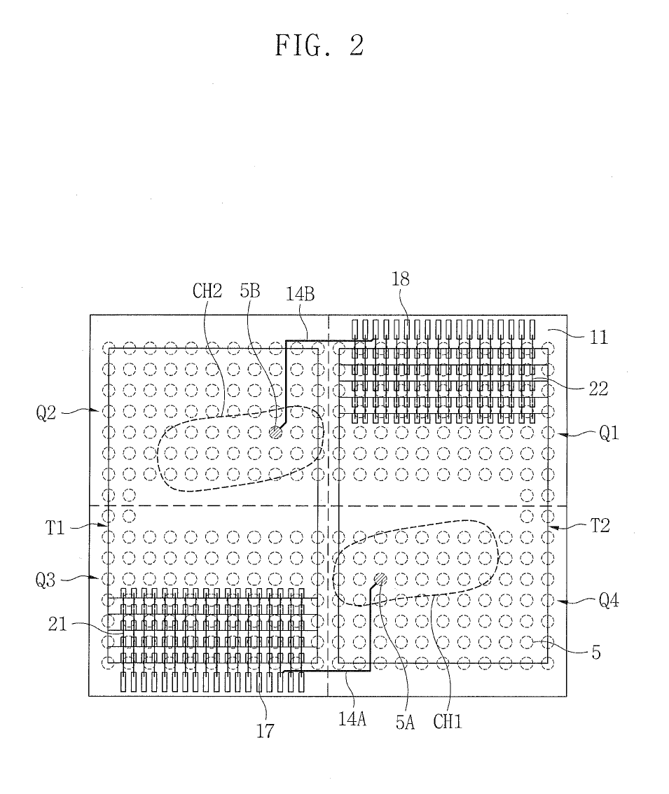

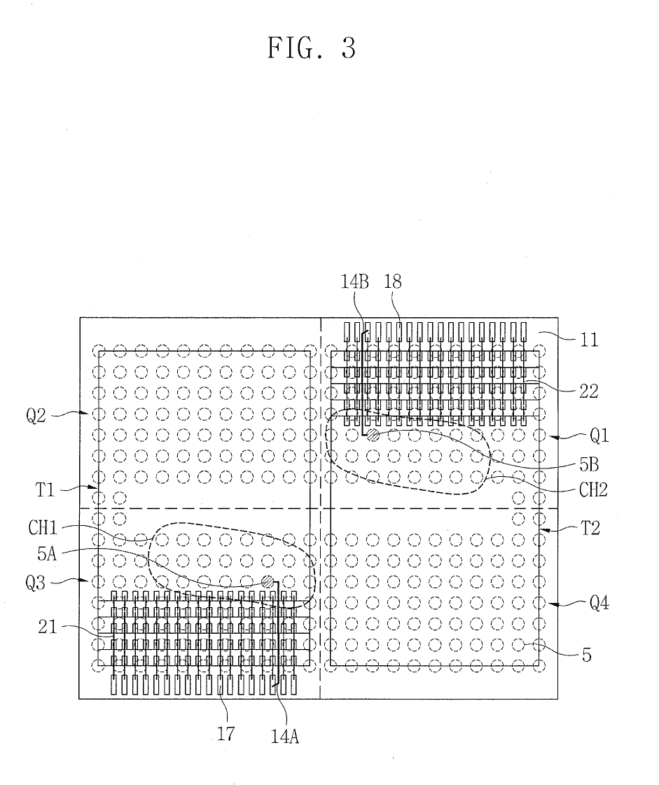

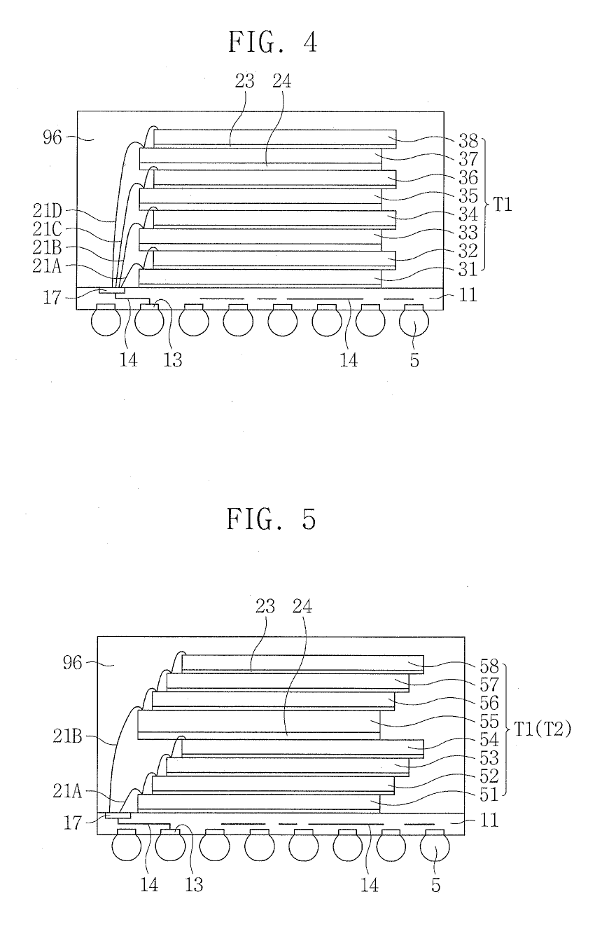

FIG. 1 is a perspective view of a semiconductor package in accordance with exemplary embodiments of the inventive concept, and FIGS. 2 and 3 are layout views of a semiconductor package in accordance with exemplary embodiments of the inventive concept. FIGS. 4 to 11 are cross-sectional views of semiconductor packages in accordance with exemplary embodiments of the inventive concept.

Referring to FIG. 1, a first tower T1 and a second tower T2 may be formed on a substrate 11. The first tower T1 may include first to eighth semiconductor chips 31, 32, 33, 34, 35, 36, 37, and 38, and the second tower T2 may include ninth to sixteenth semiconductor chips 41, 42, 43, 44, 45, 46, 47, and 48. The second tower T2 may be arranged adjacent to the first tower T1. A plurality of external terminals 5 may be formed on a bottom surface of the substrate 11. A plurality of first finger electrodes 17 and a plurality of second finger electrodes 18 may be formed on a top surface of the substrate 11. The first to eighth semiconductor chips 31, 32, 33, 34, 35, 36, 37, and 38 may be connected to the first finger electrodes 17 by first conductive wires 21. The ninth to sixteenth semiconductor chips 41, 42, 43, 44, 45, 46, 47, and 48 may be connected to the second finger electrodes 18 by second conductive wires 22. Upper ends of the first tower T1 and the second tower T2 may be arranged at the same (or substantially the same) vertical level. Upper ends of the eighth semiconductor chip 38 and the sixteenth semiconductor chip 48 may be arranged at the same (or substantially the same) vertical level.

The substrate 11 may include a rigid printed circuit board, a flexible printed circuit board, or a combination thereof. The substrate 11 may be referred to as a package board. The external terminals 5 may be exposed on the bottom surface of the substrate 11. Each of the external terminals 5 may include a solder ball, a conductive bump, a conductive paste, a lead grid array (LGA), a pin grid array (PGA), or a combination thereof.

The first finger electrodes 17 and the second finger electrodes 18 may be formed on the top surface of the substrate 11. The first finger electrodes 17 and the second finger electrodes 18 may be arranged along edges of the substrate 11. The first finger electrodes 17 may be arranged to be spaced apart from the second finger electrodes 18. Each of the first finger electrodes 17 and second finger electrodes 18 may include Ti, TiN, Ta, TaN, W, WN, Ni, Au, Ag, Pt, Ru, or a combination thereof. Each of the first conductive wires 21 and second conductive wires 22 may include a bonding wire, a beam lead, a conductive tape, or a combination thereof. For example, each of the first conductive wires 21 and second conductive wires 22 may be a gold wire or an aluminum wire.

The first to eighth semiconductor chips 31, 32, 33, 34, 35, 36, 37, and 38 and the ninth to sixteenth semiconductor chips 41, 42, 43, 44, 45, 46, 47, and 48 may be memory chips such as volatile memories or non-volatile memories. The first to eighth semiconductor chips 31, 32, 33, 34, 35, 36, 37, and 38 and the ninth to sixteenth semiconductor chips 41, 42, 43, 44, 45, 46, 47, and 48 may be the same kind of semiconductor chips. They may also be different from each other. The first to eighth semiconductor chips 31, 32, 33, 34, 35, 36, 37, and 38 and the ninth to sixteenth semiconductor chips 41, 42, 43, 44, 45, 46, 47, and 48 may have the same horizontal width, or not. For example, each of the first to eighth semiconductor chips 31, 32, 33, 34, 35, 36, 37, and 38 and ninth to sixteenth semiconductor chips 41, 42, 43, 44, 45, 46, 47, and 48 may include a flash memory. The number of the first to eighth semiconductor chips 31, 32, 33, 34, 35, 36, 37, and 38 included in the first tower T1 may be the same as the number of the ninth to sixteenth semiconductor chips 41, 42, 43, 44, 45, 46, 47, and 48 included in the second tower T2. The number in each tower may also be different. In exemplary embodiments of the inventive concept, each of the first to eighth semiconductor chips 31, 32, 33, 34, 35, 36, 37, and 38 and ninth to sixteenth semiconductor chips 41, 42, 43, 44, 45, 46, 47, and 48 may include a mobile dynamic random access memory (DRAM).

Referring to FIG. 2, the substrate 11 may include first to fourth quadrants Q1, Q2, Q3, and Q4. The external terminals 5 may configure a multi-channel. The external terminals 5 may include a first group CH1 configuring a channel 1, and a second group CH2 configuring a channel 2. The external terminals 5 may include a first external terminal 5A and a second external terminal 5B. The first external terminal 5A may be included in the first group CH1, and the second external terminal 5B may be included in the second group CH2. The second group CH2 may be arranged far from the first group CH1 in terms of operation characteristics. For example, the first group CH1 may be arranged on the fourth quadrant Q4, and the second group CH2 may be arranged on the second quadrant Q2.

The first tower T1 may be arranged on the second and third quadrants Q2 and Q3. The second tower T2 may be arranged on the first and fourth quadrants Q1 and Q4. The first finger electrodes 17 may be formed on the third quadrant Q3. The second finger electrodes 18 may be formed on the first quadrant Q1. At least one of the first finger electrodes 17 may be connected to the first external terminal 5A of the first group CH1 via a first substrate interconnection 14A, and at least one of the second finger electrodes 18 may be connected to the second external terminal 5B of the second group CH2 via a second substrate interconnection 14B.

The first quadrant Q1 may be in contact with the second quadrant Q2 and the fourth quadrant Q4, and spaced apart from the third quadrant Q3. The second quadrant Q2 may be in contact with the first quadrant Q1 and the third quadrant Q3, and spaced apart from the fourth quadrant Q4. The third quadrant Q3 may be in contact with the second quadrant Q2 and the fourth quadrant Q4, and spaced apart from the first quadrant Q1. The fourth quadrant Q4 may be in contact with the first quadrant Q1 and the third quadrant Q3, and spaced apart from the second quadrant Q2. A quadrant may be defined by the external terminals included therein.

In exemplary embodiments of the inventive concept, the external terminals 5 may configure first to fourth channels. However, more or less channels may be configured. The first group CH1 may correspond to the first and third channels, and the second group CH2 may correspond to the second and fourth channels.

Referring to FIG. 3, the external terminals 5 may include a first group CH1 configuring a channel 1, and a second group CH2 configuring a channel 2. The first group CH1 may be arranged on the third quadrant Q3, and the second group CH2 may be arranged on the first quadrant Q1. The first finger electrodes 17 may be formed on the third quadrant Q3. The second finger electrodes 18 may be formed on the first quadrant Q1. At least one of the first finger electrodes 17 may be connected to the first external terminal 5A of the first group CH1 via a first substrate interconnection 14A, and at least one of the second finger electrodes 18 may be connected to the second external terminal 5B of the second group CH2 via a second substrate interconnection 14B.

Referring to FIG. 4, the substrate 11 may include a plurality of substrate interconnections 14, a plurality of external electrodes 13, and the first and second finger electrodes 17 and 18. Each of the first and second finger electrodes 17 and 18 may be connected to the external electrodes 13 via the substrate interconnections 14. The external terminals 5 may be formed on the external electrodes 13. The substrate interconnections 14 and the external electrodes 13 may include Cu, Ti, TiN, Ta, TaN, W, WN, Ni, Au, Ag, Pt, Ru, or a combination thereof.

The first to eighth semiconductor chips 31, 32, 33, 34, 35, 36, 37, and 38 may be sequentially stacked on the substrate 11. The first semiconductor chip 31 may be attached to the substrate 11 using a first adhesive layer 23. The second semiconductor chip 32 may be mounted on the first semiconductor chip 31 using the first adhesive layer 23. The second semiconductor chip 32 may be aligned offset with the first semiconductor chip 31. The second semiconductor chip 32 and the first semiconductor chip 31 may be connected to the first finger electrode 17 using a first wire 21A. The first wire 21A may be sequentially connected to the first semiconductor chip 31 and the second semiconductor chip 32.

The third semiconductor chip 33 may be attached on the second semiconductor chip 32 using a second adhesive layer 24. In FIG. 4, for purposes of illustration, the first and second adhesive layers 23 and 24 are differentiated in terms of thickness. For example, the second adhesive layer 24 is thicker than the first adhesive layer 23. The third semiconductor chip 33 may be aligned offset with the second semiconductor chip 32, and vertically aligned with the first semiconductor chip 31. A part of the first wire 21A may pass through the second adhesive layer 24 contacting the third semiconductor chip 33. The fourth semiconductor chip 34 may be attached on the third semiconductor chip 33 using the first adhesive layer 23. The fourth semiconductor chip 34 may be aligned offset with the third semiconductor chip 33, and vertically aligned with the second semiconductor chip 32. The fourth semiconductor chip 34 and the third semiconductor chip 33 may be connected to the first finger electrode 17 using a second wire 21B. The second wire 21B may be sequentially connected to the third semiconductor chip 33 and the fourth semiconductor chip 34.

The fifth semiconductor chip 35 may be attached on the fourth semiconductor chip 34 using the second adhesive layer 24. The fifth semiconductor chip 35 may be aligned offset with the fourth semiconductor chip 34, and vertically aligned with the third semiconductor chip 33. A part of the second wire 21B may pass through the second adhesive layer 24 contacting the fifth semiconductor chip 35. The sixth semiconductor chip 36 may be attached on the fifth semiconductor chip 35 using the first adhesive layer 23. The sixth semiconductor chip 36 may be aligned offset with the fifth semiconductor chip 35, and vertically aligned with the fourth semiconductor chip 34. The sixth semiconductor chip 36 and the fifth semiconductor chip 35 may be connected to the first finger electrode 17 using a third wire 21C. The third wire 21C may be sequentially connected to the fifth semiconductor chip 35 and the sixth semiconductor chip 36.

The seventh semiconductor chip 37 may be attached on the sixth semiconductor chip 36 using the second adhesive layer 24. The seventh semiconductor chip 37 may be aligned offset with the sixth semiconductor chip 36, and vertically aligned with the fifth semiconductor chip 35. A part of the third wire 21C may pass through the second adhesive layer 24 contacting the seventh semiconductor chip 37. The eighth semiconductor chip 38 may be attached on the seventh semiconductor chip 37 using the first adhesive layer 23. The eighth semiconductor chip 38 may be aligned offset with the seventh semiconductor chip 37, and vertically aligned with the sixth semiconductor chip 36. The eighth semiconductor chip 38 and the seventh semiconductor chip 37 may be connected to the first finger electrode 17 using a fourth wire 21D. The fourth wire 21D may be sequentially connected to the seventh semiconductor chip 37 and the eighth semiconductor chip 38.

An encapsulating material 96 covering the first to eighth semiconductor chips 31, 32, 33, 34, 35, 36, 37, and 38 may be formed on the substrate 11. The encapsulating material 96 may include an epoxy molding compound (EMC). The first to eighth semiconductor chips 31, 32, 33, 34, 35, 36, 37, and 38 may be referred to as a zigzag stack. Each of the first to eighth semiconductor chips 31, 32, 33, 34, 35, 36, 37, and 38 may be the same kind of semiconductor chip. They may also be different. Each of the first to eighth semiconductor chips 31, 32, 33, 34, 35, 36, 37, and 38 may have substantially the same vertical thickness and horizontal width, or not. The first to eighth semiconductor chips 31, 32, 33, 34, 35, 36, 37, and 38 may configure the first tower T1. The first to eighth semiconductor chips 31, 32, 33, 34, 35, 36, 37, and 38 may be connected to the external terminals 5 via the first to fourth wires 21A, 21B, 21C, and 21D, the first finger electrode 17, the substrate interconnections 14, and the external electrodes 13.

The second adhesive layer 24 may be thicker than the first adhesive layer 23. The first adhesive layer 23 and the second adhesive layer 24 may include a tape-type material layer, a liquid coating cured material, or a combination thereof. The first adhesive layer 23 and the second adhesive layer 24 may include a thermal setting structure, a thermal plastic, an ultraviolet (UV) cure material, or a combination thereof. The first adhesive layer 23 and the second adhesive layer 24 may include an epoxy group, silicon group, phenol type, acid anhydride type, or amine type of hardener, an acrylic polymer, or a combination thereof. The first adhesive layer 23 and the second adhesive layer 24 may be referred to as a die attach film (DAF) or a non-conductive film (NCF). In exemplary embodiments of the inventive concept, the first adhesive layer 23 and the second adhesive layer 24 may include an underfill material.

In exemplary embodiments of the inventive concept, the external terminals 5 may be omitted. When the external terminals 5 are omitted, the external electrodes 13 may be exposed. The external electrodes 13 may include a conductive tab, a LGA, a PGA, or a combination thereof.

Referring to FIG. 5, first to fourth semiconductor chips 51, 52, 53, and 54 may be sequentially stacked on the substrate 11 using the first adhesive layer 23. Like FIG. 4, in FIG. 5 the first adhesive layer 23 is shown with less thickness than the second adhesive layer 24. The second to fourth semiconductor chips 52, 53, and 54 may be sequentially aligned offset on the first semiconductor chip 51 in a first direction. The first to fourth semiconductor chips 51, 52, 53, and 54 may be connected to a first finger electrode 17 using a first wire 21A. The first wire 21A may be sequentially connected to the first to fourth semiconductor chips 51, 52, 53, and 54. The first to fourth semiconductor chips 51, 52, 53, and 54 may be referred to as a cascade stack.

A fifth semiconductor chip 55 may be attached on the fourth semiconductor chip 54 using the second adhesive layer 24. The fifth semiconductor chip 55 may be aligned offset on the fourth semiconductor chip 54 in a second direction. The fifth semiconductor chip 55 may be vertically aligned with one of the first to third semiconductor chips 51, 52, and 53. For example, the fifth semiconductor chip 55 may be vertically aligned with the first semiconductor chip 51. Sixth to eighth semiconductor chips 56, 57, and 58 may be sequentially stacked on the fifth semiconductor chip 55 using the first adhesive layer 23. The sixth to eighth semiconductor chips 56, 57, and 58 may be sequentially aligned offset on the fifth semiconductor chip 55 in the first direction. The fifth to eighth semiconductor chips 55, 56, 57, and 58 may be connected to the first finger electrode 17 using a second wire 21B. The second wire 21B may be sequentially connected to the fifth to eighth semiconductor chips 55, 56, 57, and 58.

Each of the first to eighth semiconductor chips 51, 52, 53, 54, 55, 56, 57, and 58 may be the same kind of semiconductor chip. They may also be different. Each of the first to eighth semiconductor chips 51, 52, 53, 54, 55, 56, 57, and 58 may have substantially the same horizontal width, or not. Each of the first to fourth semiconductor chips 51, 52, 53, and 54 and sixth to eighth semiconductor chips 56, 57, and 58 may have substantially the same vertical thickness, or not. The fifth semiconductor chip 55 may have a different vertical thickness from the first to fourth semiconductor chips 51, 52, 53, and 54, and the sixth to eighth semiconductor chips 56, 57, and 58. For example, the fifth semiconductor chip 55 may be thicker than the first to fourth semiconductor chips 51, 52, 53, and 54, and the sixth to eighth semiconductor chips 56, 57, and 58. The first to eighth semiconductor chips 51, 52, 53, 54, 55, 56, 57, and 58 may configure the first tower T1. In exemplary embodiments of the inventive concept, the second tower T2 may also have a similar configuration to the first to eighth semiconductor chips 51, 52, 53, 54, 55, 56, 57, and 58. The first to eighth semiconductor chips 51, 52, 53, 54, 55, 56, 57, and 58 may be connected to external terminals 5 via the first and second wires 21A and 21B, the first finger electrode 17, substrate interconnections 14, and external electrodes 13. An encapsulating material 96 covering the first to eighth semiconductor chips 51, 52, 53, 54, 55, 56, 57, and 58 may be formed on the substrate 11.

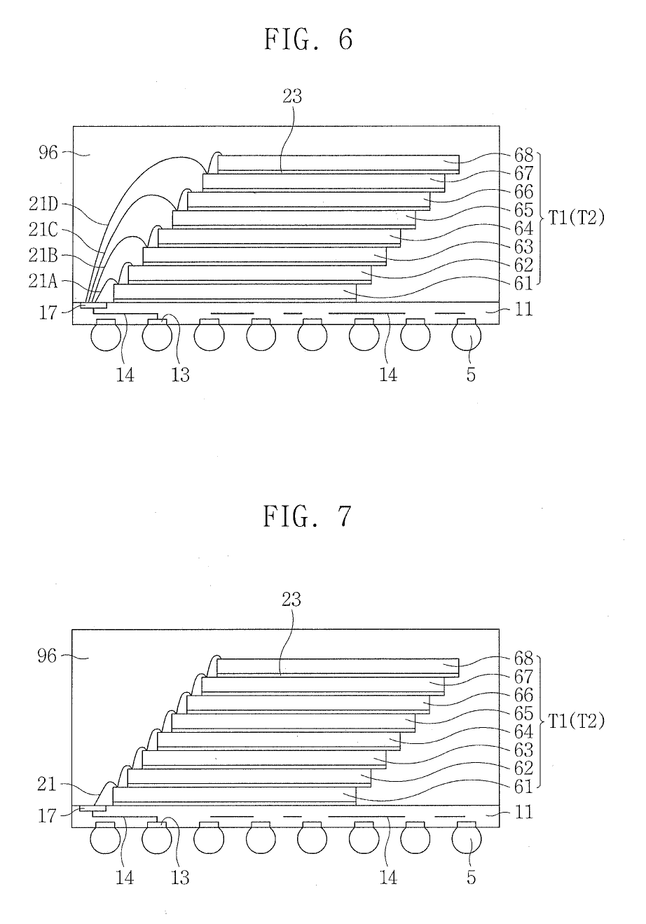

Referring to FIG. 6, first to eighth semiconductor chips 61, 62, 63, 64, 65, 66, 67, and 68 may be sequentially stacked on the substrate 11 using the first adhesive layer 23. The second to eighth semiconductor chips 62, 63, 64, 65, 66, 67, and 68 may be sequentially aligned offset on the first semiconductor chip 61. The second semiconductor chip 62 and the first semiconductor chip 61 may be connected to a first finger electrode 17 using a first wire 21A. The first wire 21A may be sequentially connected to the first semiconductor chip 61 and the second semiconductor chip 62. The fourth semiconductor chip 64 and the third semiconductor chip 63 may be connected to the first finger electrode 17 using a second wire 21B. The second wire 21B may be sequentially connected to the third semiconductor chip 63 and the fourth semiconductor chip 64. The sixth semiconductor chip 66 and the fifth semiconductor chip 65 may be connected to the first finger electrode 17 using a third wire 21C. The third wire 21C may be sequentially connected to the fifth semiconductor chip 65 and the sixth semiconductor chip 66. The eighth semiconductor chip 68 and the seventh semiconductor chip 67 may be connected to the first finger electrode 17 using a fourth wire 21D. The fourth wire 21D may be sequentially connected to the seventh semiconductor chip 67 and the eighth semiconductor chip 68.

The first to eighth semiconductor chips 61, 62, 63, 64, 65, 66, 67, and 68 may be referred to as a cascade stack. Each of the first to eighth semiconductor chips 61, 62, 63, 64, 65, 66, 67, and 68 may be the same kind of semiconductor chip. They may also be different. Each of the first to eighth semiconductor chips 61, 62, 63, 64, 65, 66, 67, and 68 may have substantially the same horizontal width and vertical thickness, or not. The first to eighth semiconductor chips 61, 62, 63, 64, 65, 66, 67, and 68 may configure a first tower T1. In exemplary embodiments of the inventive concept, a second tower T2 may also have a similar configuration to the first to eighth semiconductor chips 61, 62, 63, 64, 65, 66, 67, and 68. The first to eighth semiconductor chips 61, 62, 63, 64, 65, 66, 67, and 68 may be connected to external terminals 5 via the first to fourth wires 21A to 21D, the first finger electrode 17, substrate interconnections 14, and external electrodes 13. An encapsulating material 96 covering the first to eighth semiconductor chips 61, 62, 63, 64, 65, 66, 67, and 68 may be formed on the substrate 11.

Referring to FIG. 7, the second to eighth semiconductor chips 62, 63, 64, 65, 66, 67, and 68 may be aligned offset on the first semiconductor chip 61 in a first direction. The first to eighth semiconductor chips 61, 62, 63, 64, 65, 66, 67, and 68 may be connected to the first finger electrode 17 using a first conductive wire 21. The first conductive wire 21 may be sequentially connected to the first to eighth semiconductor chips 61, 62, 63, 64, 65, 66, 67, and 68. The first to eighth semiconductor chips 61, 62, 63, 64, 65, 66, 67, and 68 may be connected to external terminals 5 via the first wire 21, the first finger electrode 17, substrate interconnections 14, and external electrodes 13. An encapsulating material 96 covering the first to eighth semiconductor chips 61, 62, 63, 64, 65, 66, 67, and 68 may be formed on the substrate 11.

Referring to FIG. 8, first to fourth semiconductor chips 51, 52, 53, and 54 may be sequentially stacked on the substrate 11 using the first adhesive layer 23. The second to fourth semiconductor chips 52, 53, and 54 may be sequentially aligned offset on the first semiconductor chip 51 in a first direction. The first to fourth semiconductor chips 51, 52, 53, and 54 may be connected to a first finger electrode 17 using a first conductive wire 21. The first conductive wire 21 may be sequentially connected to the first to fourth semiconductor chips 51, 52, 53, and 54. The first to fourth semiconductor chips 51, 52, 53, and 54 may be referred to as a cascade stack. An encapsulating material 96 covering the first to fourth semiconductor chips 51, 52, 53, and 54 may be formed on the substrate 11. Each of the first to fourth semiconductor chips 51, 52, 53, and 54 may be the same kind of semiconductor chip. They may also be different. Each of the first to fourth semiconductor chips 51, 52, 53, and 54 may have substantially the same horizontal width and vertical thickness, or not. The first to fourth semiconductor chips 51, 52, 53, and 54 may configure the first tower T1. In exemplary embodiments of the inventive concept, the second tower T2 may also have a similar configuration to the first to fourth semiconductor chips 51, 52, 53, and 54. The first to fourth semiconductor chips 51, 52, 53 and 54 may be connected to external terminals 5 via the first wire 21, a first finger electrode 17, substrate interconnections 14, and external electrodes 13.

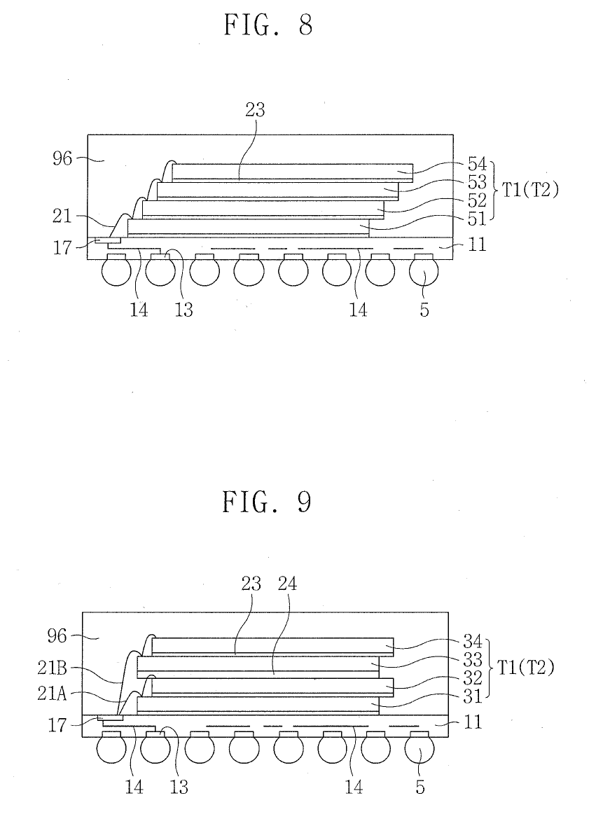

Referring to FIG. 9, the first to fourth semiconductor chips 31, 32, 33, and 34 may be sequentially stacked on the substrate 11. The first semiconductor chip 31 may be attached on the substrate 11 using a first adhesive layer 23. The second semiconductor chip 32 may be mounted on the first semiconductor chip 31 using the first adhesive layer 23. The second semiconductor chip 32 may be aligned offset with the first semiconductor chip 31. The second semiconductor chip 32 and the first semiconductor chip 31 may be connected to a first finger electrode 17 using a first wire 21A. The first wire 21A may be sequentially connected to the first semiconductor chip 31 and the second semiconductor chip 32.

The third semiconductor chip 33 may be attached on the second semiconductor chip 32 using a second adhesive layer 24. Like FIG. 4, in FIG. 9 the first adhesive layer 23 is shown with less thickness than the second adhesive layer 24. The third semiconductor chip 33 may be aligned offset with the second semiconductor chip 32, and vertically aligned with the first semiconductor chip 31. A part of the first wire 21A may pass through the second adhesive layer 24 contacting the third semiconductor chip 33. The fourth semiconductor chip 34 may be attached on the third semiconductor chip 33 using the first adhesive layer 23. The fourth semiconductor chip 34 may be aligned offset with the third semiconductor chip 33 and vertically aligned with the second semiconductor chip 32. The fourth semiconductor chip 34 and the third semiconductor chip 33 may be connected to the first finger electrode 17 using a second wire 21B. The second wire 21B may be sequentially connected to the third semiconductor chip 33 and the fourth semiconductor chip 34.

An encapsulating material 96 covering the first to fourth semiconductor chips 31, 32, 33, and 34 may be formed on the substrate 11. Each of the first to fourth semiconductor chips 31, 32, 33, and 34 may be the same kind of semiconductor chip. They may also be different. Each of the first to fourth semiconductor chips 31, 32, 33, and 34 may have substantially the same horizontal width and vertical thickness, or not. The first to fourth semiconductor chips 31, 32, 33, and 34 may configure the first tower T1. In exemplary embodiments of the inventive concept, the second tower T2 may also have a similar configuration to the first to fourth semiconductor chips 31, 32, 33, and 34. The first to fourth semiconductor chips 31, 32, 33 and 34 may be connected to external terminals 5 via the first and second wires 21A and 21B, a first finger electrode 17, substrate interconnections 14, and external electrodes 13.

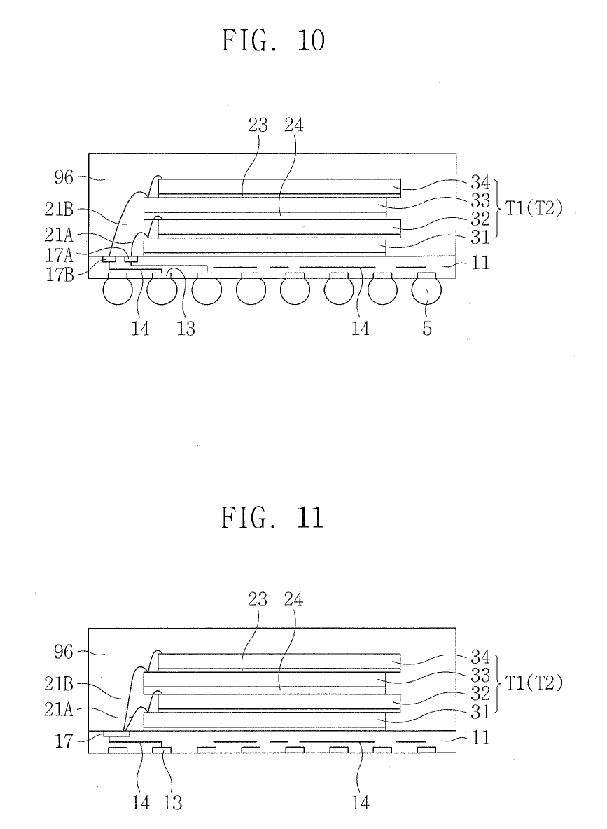

Referring to FIG. 10, the substrate 11 may include finger electrodes 17A and 17B having various arrays. Each of the first wire 21A and the second wire 21B may be connected to one of the finger electrodes 17A and 17B. The rest of the elements shown in FIG. 10 correspond to those shown in FIG. 9, for example.

Referring to FIG. 11, the external electrodes 13 may be exposed. The external electrodes 13 may include a conductive tab, a LGA, a PGA, or a combination thereof. The external terminals (reference numeral 5 in FIG. 9) may be omitted. The rest of the elements shown in FIG. 11 correspond to those shown in FIG. 9, for example.

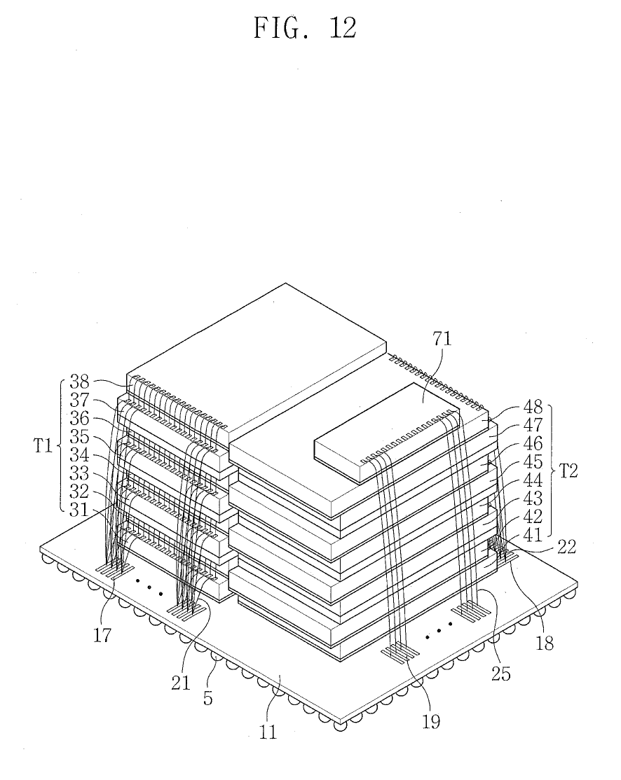

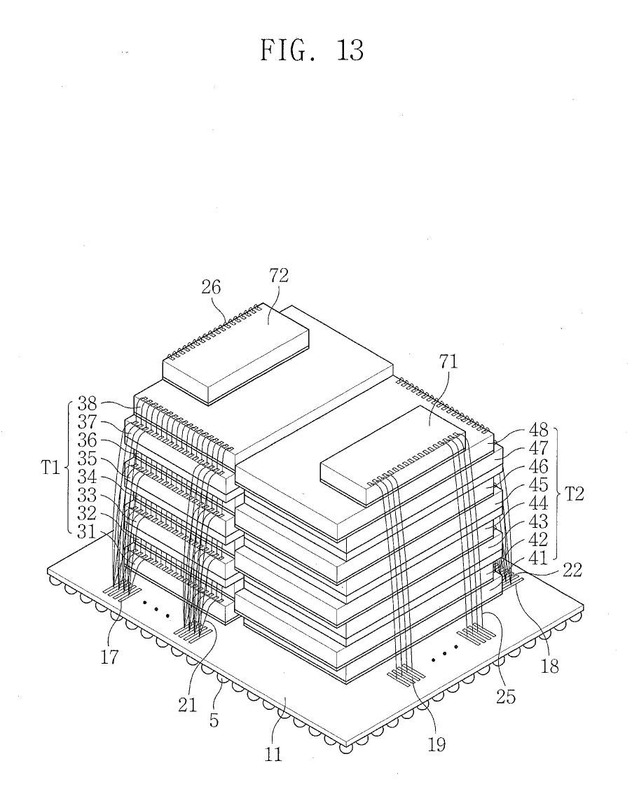

FIGS. 12 to 19 are perspective views and cross-sectional views of semiconductor packages in accordance with exemplary embodiments of the inventive concept.

FIG. 12 may be similar to FIG. 1 except that a seventeenth semiconductor chip 71 may be mounted on the second tower T2. The seventeenth semiconductor chip 71 may be connected to third finger electrodes 19 formed on the substrate 11 by third conductive wires 25. The seventeenth semiconductor chip 71 may be a different kind of chip from the first to sixteenth semiconductor chips 31, 32, 33, 34, 35, 36, 37, 38, 41, 42, 43, 44, 45, 46, 47, and 48. The seventeenth semiconductor chip 71 may be a logic chip such as a microprocessor, a controller, an application processor (AP), or a combination thereof. For example, each of the first to sixteenth semiconductor chips 31, 32, 33, 34, 35, 36, 37, 38, 41, 42, 43, 44, 45, 46, 47, and 48 may be a memory chip, and the seventeenth semiconductor chip 71 may be a controller. The seventeenth semiconductor chip 71 may have a different horizontal width from the first to sixteenth semiconductor chips 31, 32, 33, 34, 35, 36, 37, 38, 41, 42, 43, 44, 45, 46, 47, and 48.

FIG. 13 may be similar to FIG. 12 except that an eighteenth semiconductor chip 72 may be mounted on the first tower T1. The eighteenth semiconductor chip 72 may be connected to the substrate 11 by fourth conductive wires 26. The eighteenth semiconductor chip 72 may be the same kind of semiconductor chip as the seventeenth semiconductor chip 71. For example, the seventeenth semiconductor chip 71 and the eighteenth semiconductor chip 72 may be controllers. The seventeenth and eighteenth semiconductor chips 71 and 72 may be different.

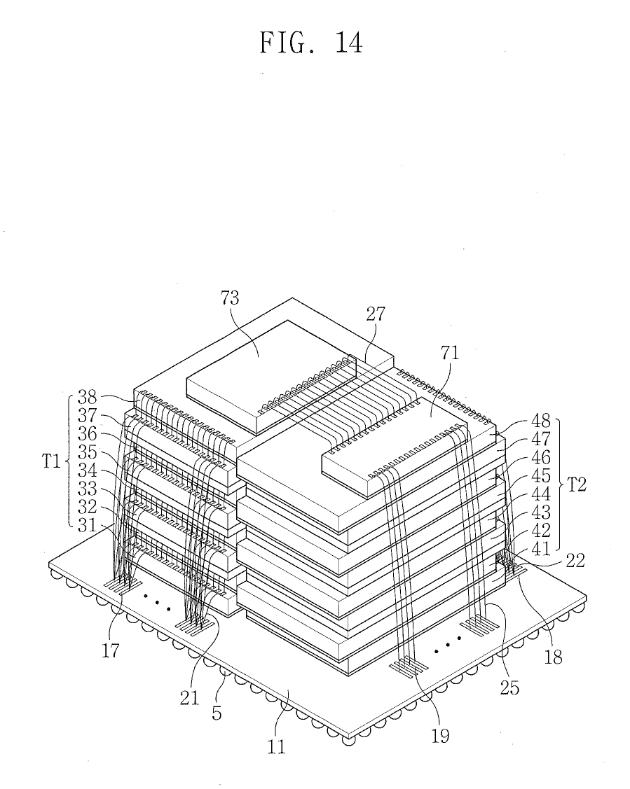

FIG. 14 may be similar to FIG. 12 except that a nineteenth semiconductor chip 73 may be mounted on the first tower T1. The nineteenth semiconductor chip 73 may be connected to the seventeenth semiconductor chip 71 by fifth conductive wires 27. The nineteenth semiconductor chip 73 may be a different kind of semiconductor chip from the seventeenth semiconductor chip 71 and the first to sixteenth semiconductor chips 31, 32, 33, 34, 35, 36, 37, 38, 41, 42, 43, 44, 45, 46, 47, and 48. The nineteenth semiconductor chip 73 may be the same kind as some of the other semiconductor chips. The nineteenth semiconductor chip 73 may have a different horizontal width from the seventeenth semiconductor chip 71 and the first to sixteenth semiconductor chips 31, 32, 33, 34, 35, 36, 37, 38, 41, 42, 43, 44, 45, 46, 47, and 48. The width of the nineteenth semiconductor chip 73 may be the same as some of the other semiconductor chips. For example, each of the first to sixteenth semiconductor chips 31, 32, 33, 34, 35, 36, 37, 38, 41, 42, 43, 44, 45, 46, 47, and 48 may include a flash memory, the seventeenth semiconductor chip 71 may be a controller, and the nineteenth semiconductor chip 73 may be a buffer chip such as a DRAM or a static random access memory (SRAM).

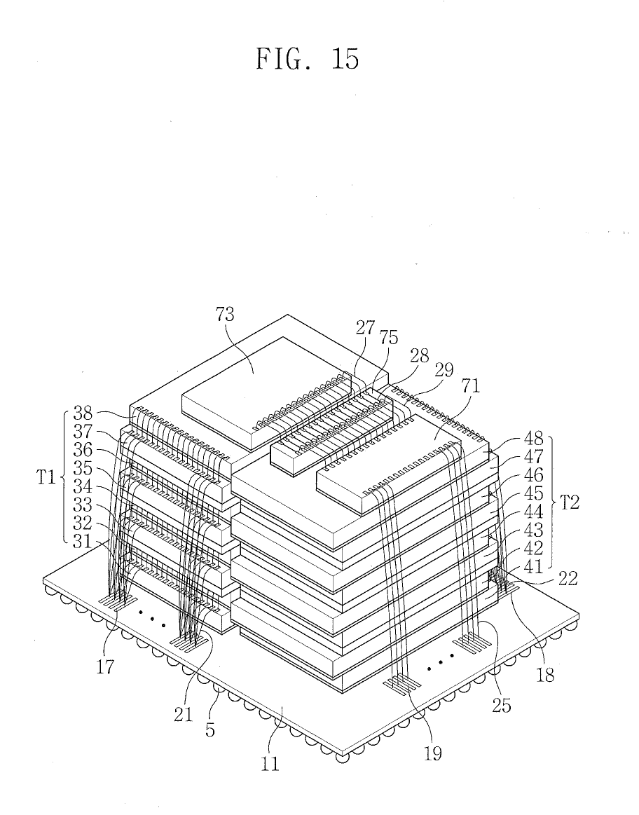

FIG. 15 may be similar to FIG. 14 except that an interposer 75 and the seventeenth semiconductor chip 71 may be mounted on the second tower T2. The nineteenth semiconductor chip 73 may be mounted on the first tower T1. The interposer 75 may include a plurality of relay interconnections 28. The nineteenth semiconductor chip 73 may be connected to the relay interconnections 28 of the interposer 75 by fifth conductive wires 27. The seventeenth semiconductor chip 71 may be connected to the relay interconnections 28 of the interposer 75 by sixth conductive wires 29. The nineteenth semiconductor chip 73 may be connected to the seventeenth semiconductor chip 71 via the fifth conductive wires 27, the relay interconnections 28, and the sixth conductive wires 29.

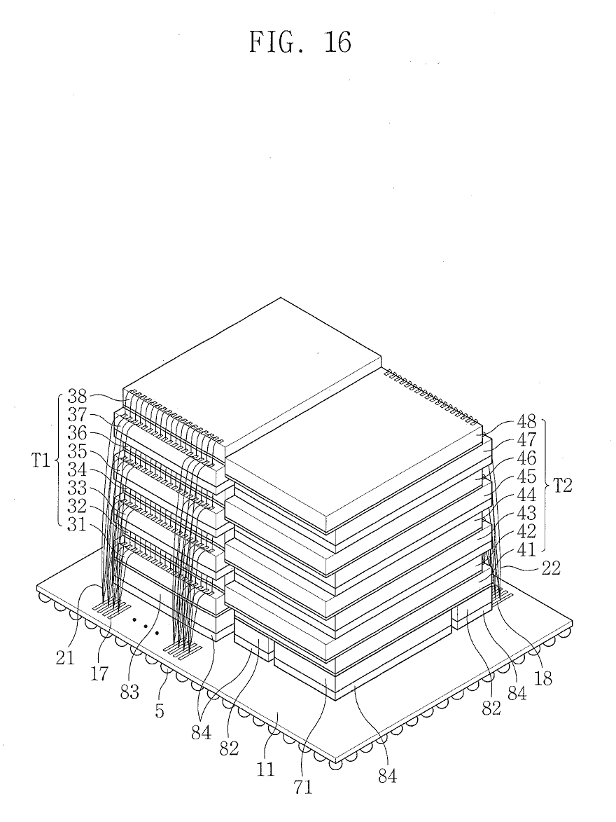

FIG. 16 may be similar to FIG. 12 except that the seventeenth semiconductor chip 71, a first spacer 82, and a second spacer 83 may be attached on the substrate 11 using third adhesive layers 84. The first tower T1 may be mounted on the second spacer 83, and the second tower T2 may be mounted on the seventeenth semiconductor chip 71 and the first spacer 82. The seventeenth semiconductor chip 71, the first spacer 82, and the second spacer 83 may have substantially the same vertical thickness, or not. Upper ends of the seventeenth semiconductor chip 71, the first spacer 82, and the second spacer 83 may be arranged at the same vertical level, or not. The second spacer 83 may have substantially the same horizontal width as the first semiconductor chip 31, or not. The second spacer 83 may be vertically aligned on a bottom of the first semiconductor chip 31.

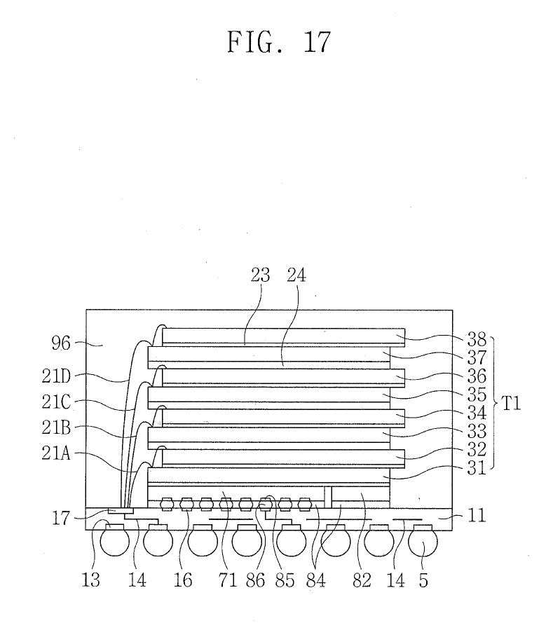

Referring to FIG. 17, the seventeenth semiconductor chip 71 and the first spacer 82 may be attached on the substrate 11 using the third adhesive layers 84. The first tower T1 may be mounted on the seventeenth semiconductor chip 71 and the first spacer 82. The seventeenth semiconductor chip 71 may include a plurality of chip pads 85. The substrate 11 may include a plurality of substrate interconnections 14, a plurality of external electrodes 13, a first finger electrode 17, and a plurality of internal electrodes 16. The plurality of internal electrodes 16 may be connected to the external electrodes 13 or the first finger electrode 17 via the substrate interconnections 14. Connection terminals 86 passing through the third adhesive layer 84 may be formed between the chip pads 85 of the seventeenth semiconductor chip 71 and the internal electrodes 16 of the substrate 11. The connection terminals 86 may include a solder ball, a conductive bump, a conductive paste, or a combination thereof. For example, each of the connection terminals 86 may be a micro bump. Like that shown in FIG. 4, the first to eighth semiconductor chips 31, 32, 33, 34, 35, 36, 37, and 38 are connected to the first finger electrode 17 via first to fourth wires 21A, 21B, 21C, and 21D. An encapsulating material 96 covering the first to eighth semiconductor chips 31, 32, 33, 34, 35, 36, 37, and 38 may be formed on the substrate 11.

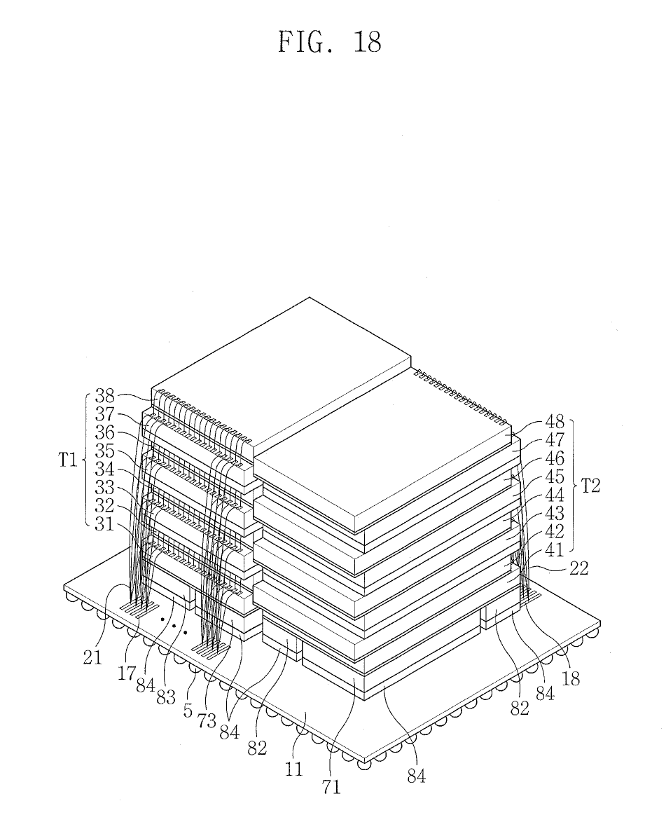

FIG. 18 may be similar to that of FIG. 14 except that the seventeenth semiconductor chip 71, the first spacer 82, the nineteenth semiconductor chip 73, and the second spacer 83 may be attached on the substrate 11 using the third adhesive layers 84. Upper ends of the seventeenth semiconductor chip 71, the first spacer 82, the nineteenth semiconductor chip 73, and the second spacer 83 may be arranged substantially at the same vertical level, or not. The first tower T1 may be mounted on the nineteenth semiconductor chip 73 and the second spacer 83, and the second tower T2 may be mounted on the seventeenth semiconductor chip 71 and the first spacer 82.

Referring to FIG. 19, which is similar to FIG. 17, a heat spreader 97 may be formed on the encapsulating material 96.

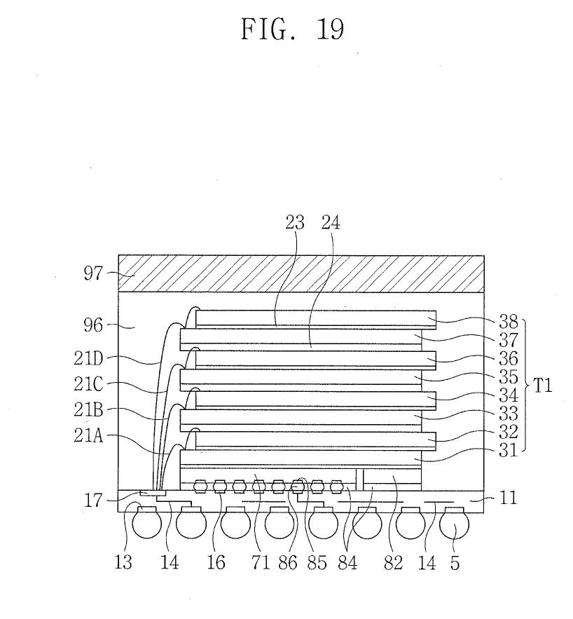

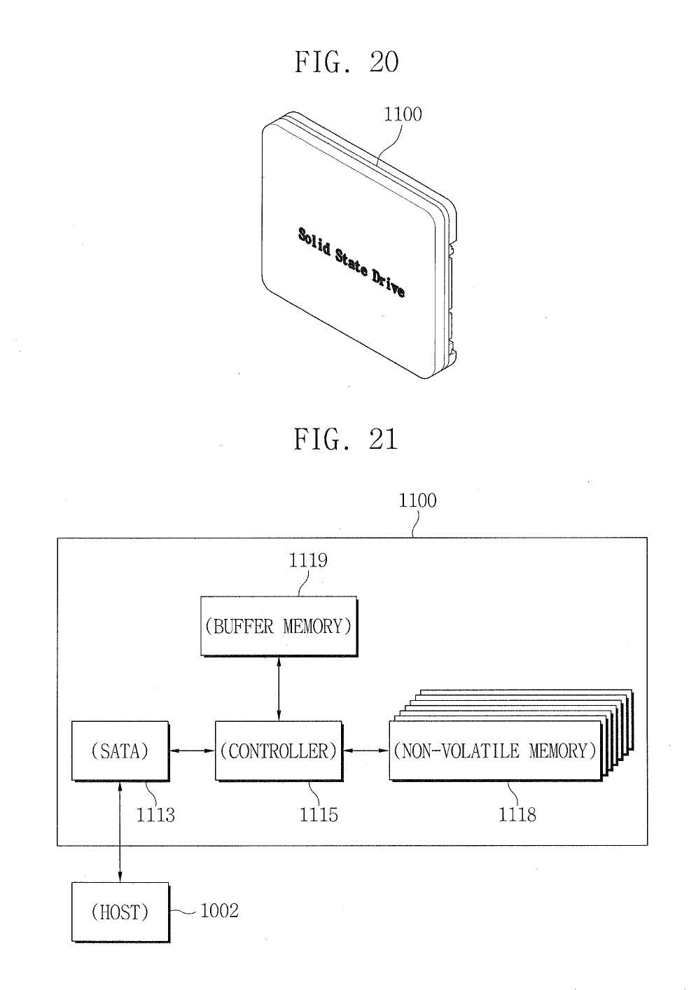

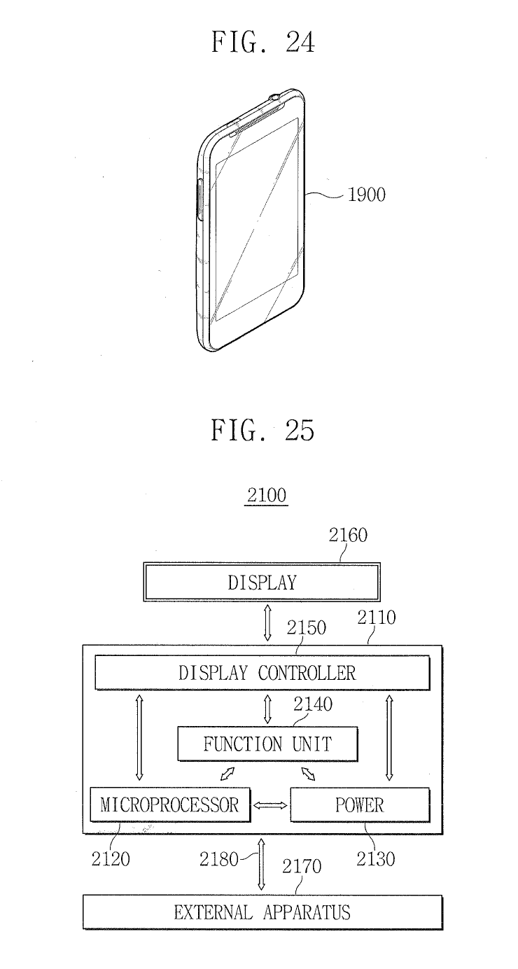

FIGS. 20 to 25 are perspective views and system block diagrams of electronic apparatuses in accordance with exemplary embodiments of the inventive concept.

Referring to FIGS. 20 and 21, the electronic apparatus in accordance with an exemplary embodiment of the inventive concept may be a data storage device, such as a solid state drive (SSD) 1100. The SSD 1100 may include an interface 1113, a controller 1115, a non-volatile memory 1118, and a buffer memory 1119. The SSD 1100 may be an apparatus that stores information using a semiconductor device. The SSD 1100 may be used in a laptop computer, a netbook, a desktop personal computer (PC), an MP3 player, or a portable storage device.

The controller 1115 may be formed close to the interface 1113 and electrically connected thereto. The controller 1115 may be a microprocessor including a memory controller and a buffer controller. The non-volatile memory 1118 may be formed close to the controller 1115 and electrically connected thereto. Data storage capacity of the SSD 1100 may correspond to the capacity of the non-volatile memory 1118. The buffer memory 1119 may be formed close to the controller 1115 and electrically connected thereto.

The interface 1113 may be connected to a host 1002, and function to send and receive electrical signals, such as data. For example, the interface 1113 may be a device using a standard such as a Serial Advanced Technology Attachment (SATA), an Integrated Drive Electronics (IDE), a Small Computer System Interface (SCSI), and/or a combination thereof. The non-volatile memory 1118 may be connected to the interface 1113 via the controller 1115. The non-volatile memory 1118 may function to store data received through the interface 1113. Even when power supplied to the SSD 1100 is interrupted, the data stored in the non-volatile memory 1118 may be retained.

The buffer memory 1119 may include a volatile memory. The volatile memory may be a DRAM and/or an SRAM. The buffer memory 1119 has a relatively faster operating speed than the non-volatile memory 1118.

Data processing speed of the interface 1113 may be relatively faster than the operating speed of the non-volatile memory 1118. Here, the buffer memory 1119 may function to temporarily store data. The data received through the interface 1113 may be temporarily stored in the buffer memory 1119 via the controller 1115, and then permanently stored in the non-volatile memory 1118 according to the data write speed of the non-volatile memory 1118. Further, frequently-used items of the data stored in the non-volatile memory 1118 may be pre-read and temporarily stored in the buffer memory 1119. In other words, the buffer memory 1119 may function to increase effective operating speed of the SSD 1100, and reduce error rate.

A part or all of the non-volatile memory, the buffer memory 1119, and the controller 1115 may have a configuration as described with reference to FIGS. 1 to 19.

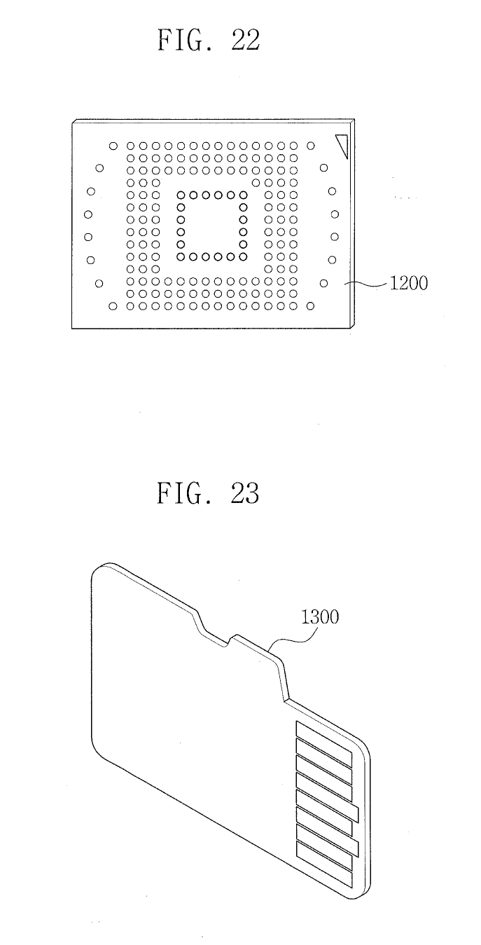

Referring to FIGS. 22 to 24, the semiconductor package described with reference to FIGS. 1 to 19 may be applied to electronic systems, such as an embedded multi-media chip (eMMC) 1200, a micro SD 1300, a smart phone 1900, a netbook, a laptop computer, an embedded solid state drive (eSSD), or a tablet PC. For example, the semiconductor package as described with reference to FIGS. 1 to 19 may be installed in a mainboard of the smart phone 1900. The semiconductor package as described with reference to FIGS. 1 to 19 may be provided to an expansion apparatus, such as the micro SD 1300, to be used with the smart phone 1900.

Referring to FIG. 25, the semiconductor package as described with reference to FIGS. 1 to 19 may be applied to an electronic system 2100. The electronic system 2100 may include a body 2110, a microprocessor unit 2120, a power unit 2130, a function unit 2140, and a display controller unit 2150. The body 2110 may be a motherboard formed of a printed circuit board (PCB). The microprocessor unit 2120, the power unit 2130, the function unit 2140, and the display controller unit 2150 may be installed on the body 2110. A display unit 2160 may be arranged inside or outside of the body 2110. For example, the display unit 2160 may be arranged on a surface of the body 2110 and display an image processed by the display controller unit 2150.

The power unit 2130 may receive a constant voltage from an external battery (not shown), etc., divide the voltage into various levels, and supply those voltages to the microprocessor unit 2120, the function unit 2140, and the display controller unit 2150, etc.

The microprocessor unit 2120 may receive a voltage from the power unit 2130 to control the function unit 2140 and the display unit 2160. The function unit 2140 may perform various functions of the electronic system 2100. For example, when the electronic system 2100 is a smart phone, the function unit 2140 may have several components which perform functions of the mobile phone such as output of an image to the display unit 2160 or output of a voice to a speaker, by dialing or communication with an external apparatus 2170. If a camera is installed, the function unit 2140 may function as a camera image processor.

In an exemplary embodiment to which the inventive concept is applied, when the electronic system 2100 is connected to a memory card, etc. in order to expand capacity, the function unit 2140 may be a memory card controller. The function unit 2140 may exchange signals with the external apparatus 2170 through a wired or wireless communication unit 2180. In addition, when the electronic system 2100 needs a universal serial bus (USB), etc. in order to expand functionality, the function unit 2140 may function as an interface controller. Further, the function unit 2140 may include a mass storage apparatus.

The semiconductor package as described with reference to FIGS. 1 to 19 may be applied to the function unit 2140.

In accordance with the exemplary embodiments of the inventive concept, a substrate including first finger electrodes and second finger electrodes spaced apart from the first finger electrodes in a diagonal direction, may be provided. First and second towers may be formed on the substrate. First semiconductor chips included in the first tower may be connected to external terminals of a first group formed on a bottom of the substrate via the first finger electrodes. Second semiconductor chips included in the second tower may be connected to external terminals of a second group formed on the bottom of the substrate via the second finger electrodes. The external terminals of the first group may configure a first channel, and the external terminals of the second group may configure a second channel. When the external terminals of the first group are formed on a fourth quadrant, the external terminals of the second group may be formed on a second quadrant. When the external terminals of the first group are formed on a third quadrant, the external terminals of the second group may be formed on a first quadrant.

The configuration of the first tower and the second tower may shorten a signaling pathway between the first and second semiconductor chips and the substrate. Due to the arrangement of the external terminals of the first and second groups, the signaling pathway between the first and second finger electrodes and the external terminals becomes uniform, simple, and shortened.

A semiconductor package in which a plurality of semiconductor chips are mounted in a single package and input/output characteristics are improved, may be implemented in accordance with exemplary embodiments of the inventive concept.

While the inventive concept has been particularly shown and described with reference to exemplary embodiments thereof, it will be understood by those of ordinary skill in the art that various changes in form and details may be made therein without departing from the spirit and scope of the present inventive concept as defined by the following claims.

What is claimed is:

1. A semiconductor package, comprising:
a substrate including a plurality of internal interconnections, first finger electrodes, and second finger electrodes, and having first to fourth quadrants;
external terminals formed on a first surface of the substrate and connected to the first and second finger electrodes via the internal interconnections;
a first tower arranged on a second surface of the substrate and including a plurality of first semiconductor chips;
first conductive wires formed between the first semiconductor chips and the first finger electrodes;
a second tower arranged on the second surface of the substrate, spaced apart from the first tower, and including a plurality of second semiconductor chips; and
second conductive wires formed between the second semiconductor chips and the second finger electrodes,
wherein the external terminals include a first group connected to the first finger electrodes and configuring a first channel, and a second group spaced apart from the first group, connected to the second finger electrodes, and configuring a second channel, and
wherein the first finger electrodes are formed on the third quadrant of the substrate, and the second finger electrodes are formed on the first quadrant of the substrate.

2. The semiconductor package of claim 1, wherein the first group of the external terminals is formed on the fourth quadrant of the substrate, and the second group of the external terminals is formed on the second quadrant of the substrate.

3. The semiconductor package of claim 1, wherein the first group of the external terminals is formed on the third quadrant of the substrate, and the second group of the external terminals is formed on the first quadrant of the substrate.

4. The semiconductor package of claim 1, wherein the first and second finger electrodes are formed adjacent to edges of the substrate.

5. The semiconductor package of claim 1, wherein each of the first and second semiconductor chips has substantially the same horizontal width.

6. The semiconductor package of claim 1, wherein upper ends of the first and second towers are arranged at substantially the same vertical level.

7. The semiconductor package of claim 1, further comprising:
a third semiconductor chip mounted on the first tower and connected to the substrate,
wherein the third semiconductor chip has a different horizontal width from the first and second semiconductor chips.

8. The semiconductor package of claim 7, further comprising:
a fourth semiconductor chip mounted on the second tower and connected to the third semiconductor chip,
wherein the fourth semiconductor chip has a different horizontal width from the first, second, and third semiconductor chips.

9. The semiconductor package of claim 1, further comprising:
a third semiconductor chip mounted between the substrate and the first tower and connected to the substrate,
wherein the third semiconductor chip has a different horizontal width from the first and second semiconductor chips.

10. The semiconductor package of claim 9, further comprising:
a fourth semiconductor chip mounted between the substrate and the second tower and connected to the substrate,
wherein the fourth semiconductor chip has a different horizontal width from the first, second, and third semiconductor chips.

11. The semiconductor package of claim 9, further comprising:
a first spacer mounted between the substrate and the first tower,
wherein upper ends of the third semiconductor chip and the first spacer are arranged at substantially the same vertical level.

12. The semiconductor package of claim 11, further comprising:
a second spacer mounted between the substrate and the second tower,
wherein upper ends of the third semiconductor chip, the first spacer, and the second spacer are arranged at substantially the same vertical level.

13. An electronic apparatus, comprising:
a controller; and
a plurality of non-volatile memory packages connected to the controller,
wherein at least one of the non-volatile memory packages comprises:
a substrate including a plurality of internal interconnections, first finger electrodes, and second finger electrodes, and having first to fourth quadrants;
external terminals formed on a first surface of the substrate and connected to the first and second finger electrodes via the internal interconnections;
a first tower arranged on a second surface of the substrate and including a plurality of first semiconductor chips;
first conductive wires formed between the first semiconductor chips and the first finger electrodes;
a second tower arranged on the second surface of the substrate, spaced apart from the first tower, and including a plurality of second semiconductor chips; and
second conductive wires formed between the second semiconductor chips and the second finger electrodes,
wherein the external terminals include a first group connected to the first finger electrodes and configuring a first channel, and a second group spaced apart from the first group, connected to the second finger electrodes, and configuring a second channel, and
wherein the first finger electrodes are formed on the third quadrant of the substrate, and the second finger electrodes are formed on the first quadrant of the substrate.

14. The electronic apparatus of claim 13, wherein the first and second finger electrodes are formed adjacent to edges of the substrate, and upper ends of the first and second towers are arranged at substantially the same vertical level.

15. The electronic apparatus of claim 13, further comprising:
an interface connected to the controller; and
a buffer memory connected to the controller.

16. A semiconductor package, comprising:
a substrate including a plurality of first electrodes and a plurality of second electrodes, wherein the first electrodes are arranged at a first edge of the substrate and the second electrodes are arranged at a second edge of the substrate;
a plurality of first semiconductor chips stacked on a first surface of the substrate and connected to the first electrodes via first wires;
a plurality of second semiconductor chips stacked on the first surface of the substrate and connected to the second electrodes via second wires; and
external terminals disposed on a second surface of the substrate and connected to the first and second semiconductor chips via internal interconnections of the substrate connected to the first and second wires,
wherein at least one of the external terminals of a first channel is connected to at least one of the first electrodes via one of the internal interconnections and at least one of the external terminals of a second channel is connected to at least one of the second electrodes via another one of the internal interconnections.

17. The semiconductor package of claim 16, wherein the first and second electrodes are spaced apart in a diagonal direction.

18. The semiconductor package of claim 16, wherein the first and second electrodes include finger electrodes.

19. The semiconductor package of claim 16, wherein the first and second wires are conductive.

20. The semiconductor package of claim 16, wherein the first semiconductor chips are spaced apart from the second semiconductor chips.
